(19) United States
(12) Patent Application Publication
(10) Pub. No.: US 2026/0316078 A1
(43) Pub. Date: Oct. 15, 2026

(54) CELL SEPARATION DEVICE AND CELL SEPARATION METHOD

(71) Applicant: CANON KABUSHIKI KAISHA, Tokyo (JP)

(72) Inventor: Kenta KAMINO, Tochigi (JP)

(73) Assignee: CANON KABUSHIKI KAISHA, Tokyo (JP)

(21) Appl. No.: 19/646,000

(22) Filed: Apr. 13, 2026

(30) Foreign Application Priority Data
Apr. 14, 2025 (JP) 2025-066297

(51) Int. Cl. B01L 3/00; G01N 33/49

(52) U.S. Cl. CPC B01L 3/502753; B01L 3/502715; G01N 33/491; B01L 2200/143; B01L 2300/047; B01L 2300/0663; B01L 2400/0487

(57) ABSTRACT

A cell separation device that separates cells from a sample including the cells includes a cell holding unit configured to hold the cells separated from the sample, a detection unit configured to detect a degree of deposition of the cells in the cell holding unit, and processing circuitry configured to determine whether the degree of deposition has reached a reference amount.

### CROSS-REFERENCE TO RELATED APPLICATIONS

This application is based upon and claims the benefit of priority from Japanese Patent Application No. 2025-066297, filed Apr. 14, 2025, the entire contents of which are incorporated herein by reference.

### FIELD

Embodiments described herein relate to a cell separation device and a cell separation method.

### BACKGROUND

In the case of separating cells such as blood cell components from a sample such as blood, centrifugal separation has heretofore been used. However, centrifugal separation is disadvantageous in that, for example, the size of a centrifugal separator is large, a relatively long time is required, and a large amount of sample is required. Accordingly, if centrifugal separation is used for Point of Care Testing (POCT), or if space-saving is to be realized in an examination room, there is a possibility that centrifugal separation is not an optimum method to separate cells.

In view of the above, a cell separation technique using a microfluidic device has recently been attracting attention as an alternative to centrifugal separation, and various methods have been proposed. However, the microfluidic device of related art does not give due consideration to a case where the amount of cells in each sample varies. In such a case, there is a possibility that cells cannot be efficiently separated from a sample.

Specific examples of this case include a case where blood collected from a patient is separated into blood cell components and plasma components. In this case, the amount of blood cell components in the blood varies depending on the red cell volume (hematocrit level) in the blood. The hematocrit level is known to be generally about 40% to 50% of blood in an adult male and is about 35% to 45% of blood in an adult female. For example, there is about a 1.4 times difference between the amount of blood cell components in blood with a hematocrit level of 35% and the amount of blood cell components in blood with a hematocrit level of 50%.

If the microfluidic device of related art is designed to be adapted to blood with a low hematocrit level, blood cell components in blood with a higher hematocrit level are quickly deposited, which may make it difficult to collect a sufficient amount of plasma components. Accordingly, the microfluidic device can be designed to be adapted to blood with a higher hematocrit level. However, in this case, conditions such as the amount of blood to be delivered to the microfluidic device and processing time are determined so as to be adapted to blood with a higher hematocrit level. As a result, there is a possibility that the process of separating blood with a low hematocrit level can be interrupted even when the microfluidic device has an allowance for holding more blood cell components. In any case, it may be difficult for the microfluidic device of related art to efficiently separate blood cell components from blood.

### BRIEF DESCRIPTION OF THE DRAWINGS

FIG. 1 is a block diagram illustrating a configuration example of a cell separation device according to a first embodiment;

FIG. 2 is a perspective view illustrating a configuration example of the cell separation device according to the first embodiment;

FIG. 3 is a schematic side view illustrating a configuration example of the cell separation device according to the first embodiment;

FIG. 4 is a schematic side view illustrating a configuration example of a detection mechanism in the cell separation device according to the first embodiment;

FIG. 5 is a schematic side view illustrating another configuration example of the detection mechanism in the cell separation device according to the first embodiment;

FIG. 6 is a flowchart illustrating an example of a cell separation process in the cell separation device according to the first embodiment;

FIG. 7 is a schematic side view illustrating an example of a change in a state of a cell holding unit in the cell separation device according to the first embodiment;

FIG. 8 is a graph illustrating an example of a change in a transmitted light intensity in the cell separation device according to the first embodiment;

FIG. 9 is a block diagram illustrating a configuration example of a cell separation device according to Modified Example 1 of the first embodiment;

FIG. 10 is a flowchart illustrating an example of the cell separation process in the cell separation device according to Modified Example 1 of the first embodiment;

FIG. 11 is a schematic side view illustrating a configuration example of a cell separation device according to Modified Example 2 of the first embodiment;

FIG. 12 is a schematic side view illustrating another configuration example of the cell separation device according to Modified Example 2 of the first embodiment;

FIG. 13 is a block diagram illustrating a configuration example of a cell separation device according to a second embodiment;

FIG. 14 is a schematic side view illustrating a configuration example of the cell separation device according to the second embodiment;

FIG. 15 is a flowchart illustrating an example of the cell separation process in the cell separation device according to the second embodiment;

FIG. 16 is a block diagram illustrating a configuration example of a cell separation device according to a third embodiment;

FIG. 17 is a schematic side view illustrating a configuration example of the cell separation device according to the third embodiment; and

FIG. 18 is a flowchart illustrating an example of the cell separation process in the cell separation device according to the third embodiment.

### DETAILED DESCRIPTION

According to an aspect of the disclosure, a cell separation device that separates cells from a sample including the cells includes a cell holding unit configured to hold the cells separated from the sample, a detection unit configured to detect a degree of deposition of the cells in the cell holding unit, and processing circuitry configured to determine whether the degree of deposition has reached a reference amount.

Various Embodiments will be described hereinafter with reference to the accompanying drawings.

A cell separation device and a cell separation method according to embodiments will be described below with reference to the drawings. In the following description, constituent elements having substantially the same functions and configurations are denoted by the same reference numerals, and a repetitive description thereof will be made only when necessary.

### First Embodiment

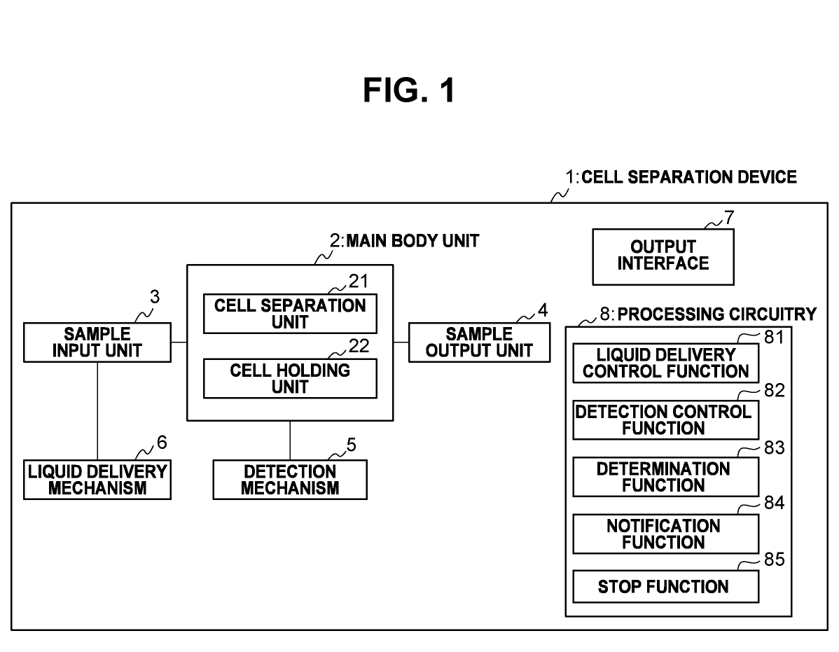

FIG. 1 is a block diagram illustrating a configuration example of a cell separation device 1 according to a first embodiment. The cell separation device 1 is a device that separates cells from a sample including the cells. The sample is, for example, blood collected from a patient. If the sample is blood, cells included in the sample are, for example, blood cells.

As illustrated in FIG. 1, the cell separation device 1 according to the first embodiment includes a main body unit 2, a sample input unit 3, a sample output unit 4, a detection mechanism 5, a liquid delivery mechanism 6, an output interface 7, and processing circuitry 8.

The main body unit 2 is a main body portion of the cell separation device 1. In the main body unit 2, a flow path for delivering a sample liquid is provided. As a material for the main body unit 2, for example, any material that can be generally applied to a microfluidic device can be used. Examples of the material include polydimethylsiloxane (PDMS), Cyclo Olefin Polymer (COP), polycarbonate (PC), and glass.

The main body unit 2 includes, for example, a cell separation unit 21 and a cell holding unit 22. The cell separation unit 21 is provided on the flow path in the main body unit 2 and separates cells in the sample delivered to the main body unit 2. The cell separation unit 21 is provided on a branch path branched from the flow path in the main body unit 2 or on the flow path in the main body unit 2, and is composed of a filter configured to capture cells in the sample. The cell separation unit 21 is fluidically connected to each of the cell holding unit 22, the sample input unit 3, and the sample output unit 4.

The cell holding unit 22 holds the cells that are separated from the sample by the cell separation unit 21. If the cell separation unit 21 is provided on the branch path, the cell holding unit 22 is, for example, a groove that can accommodate the cells separated by the cell separation unit 21. If the cell separation unit 21 is a filter provided on the flow path in the main body unit 2, for example, the filter also functions as the cell holding unit 22.

The sample input unit 3 is provided on the main body unit 2 and inputs the sample into the main body unit 2. The sample input unit 3 is, for example, an opening formed in the main body unit 2. This opening is an inlet of the flow path in the main body unit 2. The sample input unit 3 is connected to the liquid delivery mechanism 6 to be described below. The sample input unit 3 may be fluidically connected to the main body unit 2 and may be composed of an open system whose upper part is open, such as a container. In this case, a probe or the like discharges the sample to the sample input unit 3, thereby inputting the sample into the main body unit 2.

The sample output unit 4 is provided on the main body unit 2 and outputs, from the main body unit 2, the sample from which cells have been removed by the cell separation unit 21. In the following description, the sample from which cells have been removed by the cell separation unit 21 is referred to as "supernatant of sample", or is simply referred to as "supernatant". If the sample is blood, the supernatant of sample is a plasma component or a serum component. The sample output unit 4 is, for example, an opening formed in the main body unit 2. This opening is an outlet of the flow path in the main body unit 2. The sample output unit 4 may be fluidically connected to the main body unit 2 and may be composed of an open system whose upper part is open, such as a container. In this case, a probe or the like (not illustrated) can aspirate and collect the supernatant output from the sample output unit 4. In another example, the sample output unit 4 may be connected to a flow path for use in subsequent testing.

The detection mechanism 5 detects the degree of deposition of cells in the cell holding unit 22. The detection mechanism 5 obtains, as the degree of deposition, for example, optical information about the cells deposited in the cell holding unit 22. In the first embodiment, the detection mechanism 5 obtains, as optical information, a transmitted light intensity as the intensity of light that is transmitted through the cells deposited in the cell holding unit 22. The detection mechanism 5 may obtain, as optical information, the absorbance of the cells deposited in the cell holding unit 22, the intensity of scattered light, and the like. The detection mechanism 5 may be integrated with the main body unit 2, or may be separated from the main body unit 2. The detection mechanism 5 corresponds to a detection unit according to the first embodiment.

The liquid delivery mechanism 6 delivers the sample liquid to the main body unit 2 including the cell holding unit 22 from a sample container such as a blood collection tube. For example, the liquid delivery mechanism 6 includes a pump and a pipe that are fluidically connected to the sample input unit 3, and delivers the sample liquid to the flow path in the main body unit 2 from the sample container through the sample input unit 3. The liquid delivery mechanism 6 corresponds to a liquid delivery unit according to the first embodiment.

The output interface 7 is connected to the processing circuitry 8 and outputs signals supplied from the processing circuitry 8. The output interface 7 is implemented by, for example, display circuitry, print circuitry, or an audio device. Examples of the display circuitry include a cathode-ray tube (CRT) display, a liquid crystal display, an organic electroluminescence (EL) display, a light-emitting diode (LED) display, and a plasma display. Examples of the display circuitry also include processing circuitry that converts data representing a display target into a video signal and outputs the video signal to an external device. Examples of the print circuitry include a printer. Examples of the print circuitry also include output circuitry that outputs data representing a print target to an external device. Examples of the audio device include a speaker. Examples of the audio device also include output circuitry that outputs an audio signal to an external device.

The processing circuitry 8 is control circuitry that controls an overall operation of the cell separation device 1, and also functions as arithmetic circuitry that performs various arithmetic operations. In the first embodiment, the processing circuitry 8 includes a liquid delivery control function 81, a detection control function 82, a determination function 83, a notification function 84, and a stop function 85.

The liquid delivery control function 81 controls the delivery of the sample by the liquid delivery mechanism 6. The liquid delivery control function 81 receives, for example, a cell separation process start instruction from a user, such as a doctor or a medical technologist, via an input interface (not illustrated). The liquid delivery control function 81 causes the liquid delivery mechanism 6 to start delivery of the sample based on this instruction. The liquid delivery control function 81 may control delivery of the sample by the liquid delivery mechanism 6 based on a program stored in storage circuitry (not illustrated).

In the first embodiment, the liquid delivery control function 81 controls the liquid delivery mechanism 6 to continuously supply the sample. Alternatively, the liquid delivery control function 81 may control the liquid delivery mechanism 6 to intermittently supply the sample. In this case, the liquid delivery control function 81 controls, for example, the pump of the liquid delivery mechanism 6 to repeatedly deliver a prescribed amount of liquid periodically.

The detection control function 82 controls the detection of the degree of deposition by the detection mechanism 5. Specifically, the detection control function 82 controls the detection mechanism 5 to cause the detection mechanism 5 to detect the degree of deposition of cells in the cell holding unit 22. In the first embodiment, the detection control function 82 causes the detection mechanism 5 to obtain the transmitted light intensity related to the cells deposited in the cell holding unit 22.

The determination function 83 determines whether the degree of deposition of cells in the cell holding unit 22 has reached a reference amount. In the first embodiment, the determination function 83 determines whether the transmitted light intensity obtained by the detection mechanism 5 is less than or equal to a threshold. If it is determined that the transmitted light intensity is less than or equal to the threshold, the determination function 83 determines that the degree of deposition of cells in the cell holding unit 22 has reached the reference amount. On the other hand, if it is determined that the transmitted light intensity is not less than or equal to the threshold, the determination function 83 determines that the degree of deposition of cells in the cell holding unit 22 has not reached the reference amount. The determination function 83 corresponds to a determination unit according to the first embodiment.

The reference amount used for determination by the determination function 83 will now be described. The reference amount is set to a range in which the degree of separation of cells in the cell holding unit 22 can be maintained, for example, if the degree of deposition of cells in the cell holding unit 22 is less than or equal to the reference amount. Specifically, the reference amount is set to satisfy the condition that the amount of cells to be contaminated in the supernatant output from the sample output unit 4 can be reduced so that the remaining cells do not affect the subsequent testing if the degree of deposition of cells in the cell holding unit 22 is less than or equal to the reference amount.

This reference amount is determined by, for example, experiments, simulations, or calculations based on a theory such as hydrodynamics. In the case of determining the reference amount by experiments or simulations, the amount of cells that are deposited in the cell holding unit 22 and leak into the sample output unit 4 during delivery of the sample is measured or simulated, and the reference amount is set to a range in which the amount of leaked cells is less than or equal to a certain value. In the case of determining the reference amount by calculations based on a theory, the reference amount is determined based on, for example, the dimensions of each unit of the main body unit 2 and the amount of the sample liquid to be delivered per unit time by the liquid delivery mechanism 6. In the following description, the amount of the sample liquid to be delivered per unit time is simply referred to as the "amount of liquid to be delivered".

The notification function 84 notifies the user of the result of the determination by the determination function 83 via the output interface 7. For example, if the output interface 7 includes a colored lamp, the notification function 84 lights the lamp in various colors depending on the result of the determination by the determination function 83. Specifically, the notification function 84 lights the lamp in red when it is determined that the degree of deposition has not reached the reference amount, and lights the lamp in green when it is determined that the degree of deposition has reached the reference amount. This configuration enables the user to easily recognize the result of the determination by the determination function 83. The notification function 84 may be omitted. The notification function 84 corresponds to a notification unit according to the first embodiment.

The stop function 85 stops delivery of the sample liquid by the liquid delivery mechanism 6 based on the degree of deposition of cells in the cell holding unit 22 detected by the detection mechanism 5. In the first embodiment, if the determination function 83 determines that the degree of deposition has reached the reference amount, the stop function 85 stops delivery of the sample liquid by the liquid delivery mechanism 6. The stop function 85 corresponds to a stop unit according to the first embodiment.

In this case, for example, processing functions to be executed by the liquid delivery control function 81, the detection control function 82, the determination function 83, the notification function 84, and the stop function 85, which are constituent elements of the processing circuitry 8 illustrated in FIG. 1, are recorded on storage circuitry in the form of a program that can be executed by a computer. The processing circuitry 8 is, for example, a processor. The processor that constitutes the processing circuitry 8 reads out programs from the storage circuitry and executes the programs to thereby implement the functions corresponding to the read programs. In other words, the processing circuitry 8 in a state where programs are read out includes the functions included in the processing circuitry 8 illustrated in FIG. 1.

While FIG. 1 illustrates an example where the liquid delivery control function 81, the detection control function 82, the determination function 83, the notification function 84, and the stop function 85 are implemented by a single processing circuitry 8, the first embodiment is not limited to this example. For example, the processing circuitry 8 may be composed of a combination of a plurality of independent processors, and each processor may execute programs to thereby implement the functions corresponding to the programs. The processing functions of the processing circuitry 8 may be achieved through distribution or integration to a single processing circuitry or a plurality of processing circuitries as appropriate.

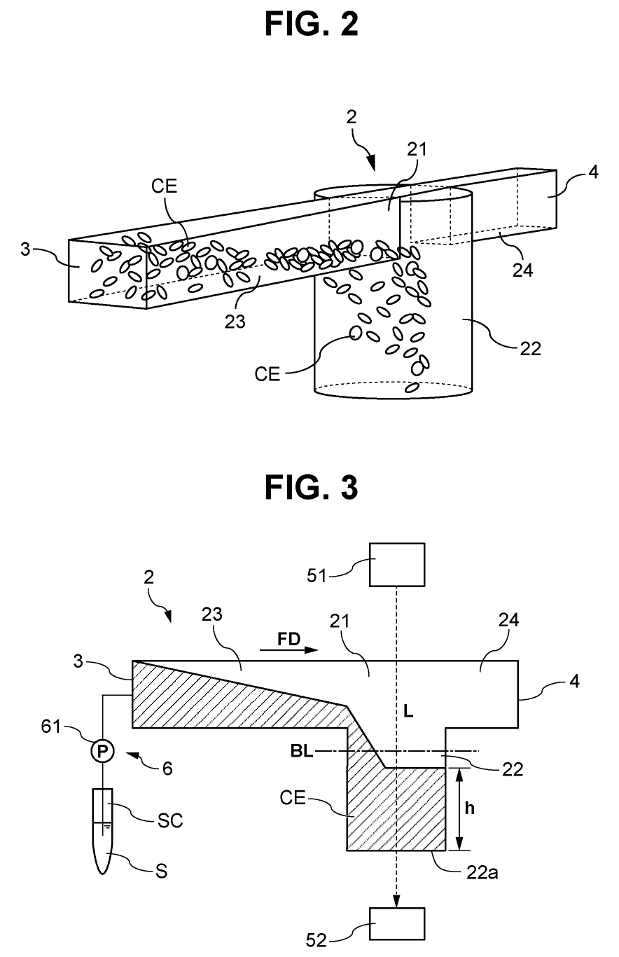

Next, a specific configuration example of the cell separation device 1 according to the first embodiment will be described with reference to FIGS. 2 and 3. FIG. 2 is a perspective view illustrating a configuration example of the cell separation device 1 according to the first embodiment. FIG. 3 is a schematic side view illustrating a configuration example of the cell separation device 1 according to the first embodiment.

As illustrated in FIGS. 2 and 3, the main body unit 2 according to the first embodiment has a substantially T-shaped side surface. Each unit of the main body unit 2 is formed in a hollow shape, and the flow path through which a sample S flows is provided in the main body unit 2. In the examples illustrated in FIGS. 2 and 3, the main body unit 2 includes the cell separation unit 21, the cell holding unit 22, a flow path 23, and a flow path 24. The sample input unit 3 is an opening formed in the side surface of the main body unit 2 where the flow path 23 is located, and the sample output unit 4 is an opening formed in the side surface of the main body unit 2 where the flow path 24 is located.

The cell separation unit 21 is composed of a T-shaped branch path and is fluidically connected to each of the cell holding unit 22, the flow path 23, and the flow path 24. The sample S delivered from a sample container SC reaches the cell separation unit 21 through the flow path 23. After that, the cell separation unit 21 separates the sample S into cells CE and supernatant (not illustrated).

The cell holding unit 22 is a three-dimensional groove provided below the cell separation unit 21, and includes a space in which a certain amount of cells CE can be held. In the first embodiment, the cells CE in the sample S that are separated by the cell separation unit 21 descend with gravity and are deposited in the cell holding unit 22. In the example illustrated in FIG. 3, the height of the cells CE deposited in the cell holding unit 22 is indicated by "h". In the first embodiment, a bottom portion 22a of the cell holding unit 22 is hermetically sealed, so that the amount of deposited cells CE gradually increases. The bottom portion 22a of the cell holding unit 22 may not be hermetically sealed and may be formed so as to be freely opened or closed by a valve or the like.

The flow path 23 is provided between the sample input unit 3 and the cell separation unit 21. The sample S in the sample container SC is delivered to the sample input unit 3 by a pump 61 included in the liquid delivery mechanism 6, and flows along a direction indicated by "FD" in the flow path 23. The length of the flow path 23 along the flow direction FD may be changed depending on the viscosity of the sample S, the specific gravity of the cells CE and supernatant, the amount of the sample S to be delivered by the liquid delivery mechanism 6, and the like.

The flow path 24 is provided between the cell separation unit 21 and the sample output unit 4. The supernatant of the sample S from which the cells CE are removed by the cell separation unit 21 is output from the sample output unit 4 through the flow path 24. The length of the flow path 24 along the flow direction FD may be changed depending on the viscosity of the sample S, the specific gravity of the cells CE and supernatant, the amount of the sample S to be delivered by the liquid delivery mechanism 6, and the like.

In the example illustrated in FIG. 2, the cell separation unit 21 and the cell holding unit 22 have a cylindrical shape. The shape of the cell separation unit 21 and the cell holding unit 22 is not limited to the cylindrical shape. The cell separation unit 21 and the cell holding unit 22 may have any other shape such as a rectangular tube shape. In the example illustrated in FIG. 2, the cell separation unit 21 and the cell holding unit 22 have a width greater than that of the flow path 23 and the flow path 24. The width of the cell separation unit 21 and the cell holding unit 22 is not limited to this example. The cell separation unit 21 and the cell holding unit 22 may have a width that is substantially the same as the width of the flow path 23 and the flow path 24.

As illustrated in FIG. 3, in the first embodiment, the detection mechanism 5 includes a light-emitting unit 51 and a light-receiving unit 52. The light-emitting unit 51 includes, for example, a white light source and a monochromator, and emits light obtained by collimating white light from the white light source by the monochromator to the cell holding unit 22. With this configuration, the light-emitting unit 51 emits light with one or more wavelengths to the cell holding unit 22. The light emitted from the light-emitting unit 51 passes through the cells CE deposited in the cell holding unit 22 along a light path L and is received by the light-receiving unit 52. The light-receiving unit 52 obtains the intensity of the light as the transmitted light intensity related to the cells CE deposited in the cell holding unit 22. The transmitted light intensity obtained by the light-receiving unit 52 varies depending on the height h of the cells CE deposited in the cell holding unit 22. More specifically, the transmitted light intensity decreases as the height h increases. Thus, the detection mechanism 5 can detect the height h of the cells CE deposited in the cell holding unit 22 based on the obtained transmitted light intensity.

In the first embodiment, the reference amount for the degree of deposition of the cells CE in the cell holding unit 22 is defined as, for example, the height from the bottom portion 22a of the cell holding unit 22 to a baseline BL. Specifically, if the height h detected by the detection mechanism 5 is less than the height from the bottom portion 22a of the cell holding unit 22 to the baseline BL, the determination function 83 of the processing circuitry 8 determines that the degree of deposition has not reached the reference amount. On the other hand, if the height h detected by the detection mechanism 5 is more than or equal to the height from the bottom portion 22a of the cell holding unit 22 to the baseline BL, the determination function 83 determines that the degree of deposition has reached the reference amount.

As illustrated in FIG. 3, in the first embodiment, the light-emitting unit 51 and the light-receiving unit 52 are provided along a longitudinal direction, that is, the direction in which the cells CE are deposited in the cell holding unit 22. This configuration enables the detection mechanism 5 to detect a detailed change in the amount of the cells CE deposited in the cell holding unit 22.

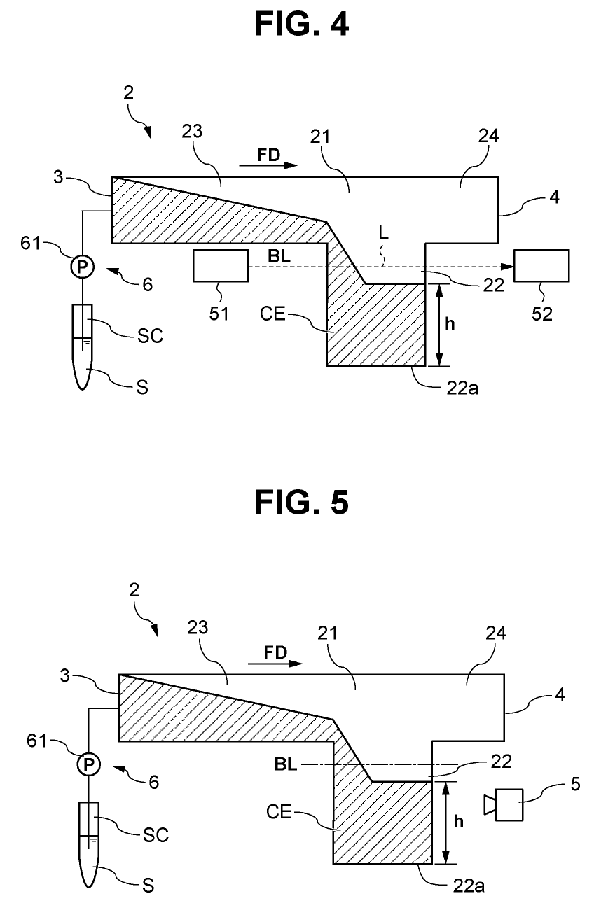

The light-emitting unit 51 and the light-receiving unit 52 may be provided along any direction other than the direction illustrated in FIG. 3. FIG. 4 is a schematic side view illustrating a configuration example of the detection mechanism 5 in the cell separation device 1 according to the first embodiment. As illustrated in FIG. 4, the light-emitting unit 51 and the light-receiving unit 52 may be provided along, for example, a lateral direction so that the light path L is aligned with the baseline BL. In this case, the detection mechanism 5 can detect at least whether the height h of the cells CE deposited in the cell holding unit 22 has exceeded the baseline BL.

The configuration of the detection mechanism 5 is not limited to the configuration including the light-emitting unit 51 and the light-receiving unit 52. FIG. 5 is a schematic side view illustrating another configuration example of the detection mechanism 5 in the cell separation device 1 according to the first embodiment. As illustrated in FIG. 5, the detection mechanism 5 may be an image sensor such as an optical camera. This image sensor obtains, for example, an image of the cells CE deposited in the cell holding unit 22. The obtained image is analyzed by the processing circuitry 8 or the like, so that the height h of the cells CE deposited in the cell holding unit 22 can be calculated.

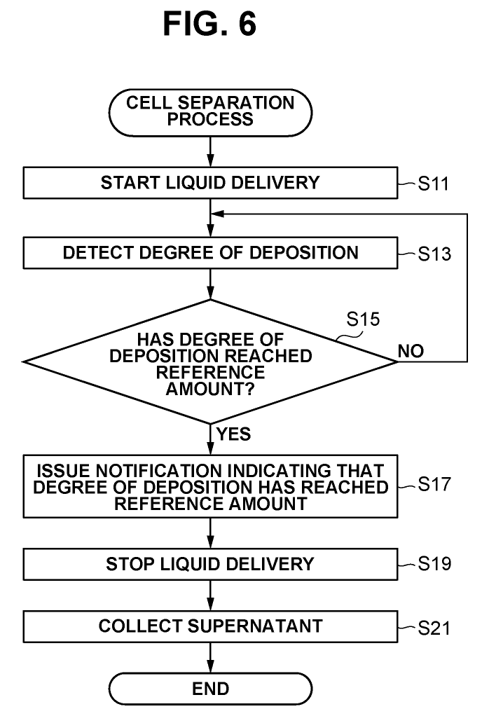

Next, an example of a cell separation process to be executed by the cell separation device 1 having a configuration as described above will be described with reference to FIG. 6. FIG. 6 is a flowchart illustrating an example of the cell separation process in the cell separation device 1 according to the first embodiment. This cell separation process is an operation to be executed, for example, when the user separates the cells CE included in the sample S by the cell separation device 1.

First, as illustrated in FIG. 6, in step S11, the cell separation device 1 starts delivery of the sample S. More specifically, the liquid delivery control function 81 of the processing circuitry 8 controls the operation of the pump 61 illustrated in FIG. 3 to aspirate the sample S including the cells CE from the sample container SC and deliver the sample S to the main body unit 2 through the sample input unit 3. Along with the delivery of the sample S, the cell separation unit 21 separates the cells CE in the sample S and the cell holding unit 22 holds the cells CE separated from the sample S. Thus, the cells CE are deposited in the cell holding unit 22.

Next, as illustrated in FIG. 6, in step S13, the cell separation device 1 detects the degree of deposition of the cells CE. More specifically, the detection control function 82 of the processing circuitry 8 controls the light-emitting unit 51 and the light-receiving unit 52 illustrated in FIG. 3 to obtain the intensity of light that is transmitted through the cells CE deposited in the cell holding unit 22.

Next, as illustrated in FIG. 6, in step S15, the cell separation device 1 determines whether the degree of deposition of the cells CE has reached the reference amount. More specifically, the determination function 83 of the processing circuitry 8 determines whether the transmitted light intensity obtained by the detection control function 82 of the processing circuitry 8 is less than or equal to a threshold.

If it is determined that the degree of deposition has not reached the reference amount (NO in step S15), the processing returns to step S13 and the cell separation device 1 repeatedly performs the operation of steps S13 and S15. While the operation of steps S13 and S15 is repeatedly performed, the sample S is continuously delivered by the liquid delivery mechanism 6.

On the other hand, if it is determined that the degree of deposition has reached the reference amount (YES in step S15), the processing proceeds to step S17. In step S17, the cell separation device 1 issues a notification indicating that the degree of deposition of the cells CE has reached the reference amount. More specifically, the notification function 84 of the processing circuitry 8 illustrated in FIG. 1 controls the output interface 7 to issue a notification indicating that the degree of deposition of the cells CE has reached the reference amount to the user.

Next, as illustrated in FIG. 6, in step S19, the cell separation device 1 stops delivery of the sample S. More specifically, the stop function 85 of the processing circuitry 8 stops the operation of the pump 61 illustrated in FIG. 3 to stop delivery of the sample S from the sample container SC.

Next, as illustrated in FIG. 6, in step S21, the cell separation device 1 collects the supernatant. More specifically, the supernatant output from the sample output unit 4 is aspirated by a probe or the like (not illustrated). The above-described steps are carried out and the operation of the cell separation device 1 according to the first embodiment ends.

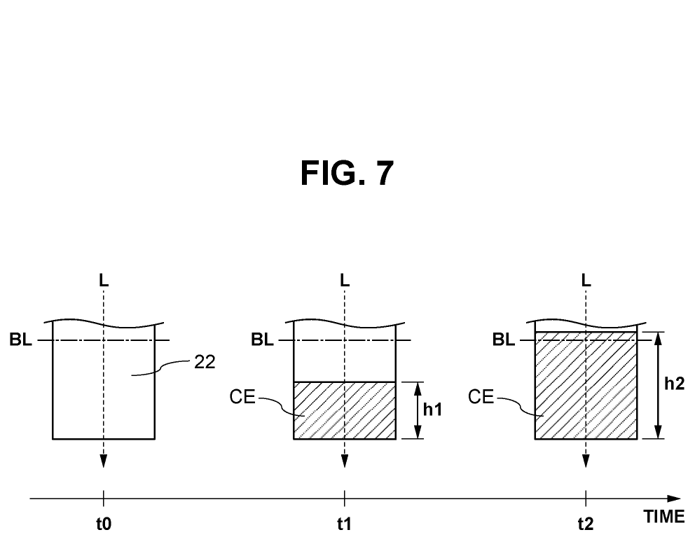

A change in the state of the cell holding unit 22 in steps S11 to S15 described above will now be described in detail with reference to FIG. 7. FIG. 7 is a schematic side view illustrating an example of a change in the state of the cell holding unit 22 in the cell separation device 1 according to the first embodiment.

As illustrated in FIG. 7, at time t0, the delivery of the sample S is started. Time t0 corresponds to a timing when step S11 illustrated in FIG. 6 is executed. At time t0, the cells CE are not deposited in the cell holding unit 22. After that, along with the delivery of the sample S, the cells CE in the sample S are separated by the cell separation unit 21 and the cells CE are deposited in the cell holding unit 22. For example, at time t1, the cells CE are deposited to a height h1 in the cell holding unit 22. At time t2, the cells CE are deposited to a height h2 in the cell holding unit 22.

During the period from time t0 to time t2, the operation of steps S13 and S15 illustrated in FIG. 6 is repeatedly performed. As illustrated in FIG. 7, during the period from time t0 to time t1, the height of the deposited cells CE is lower than the baseline BL. Accordingly, during the period from time t0 to time t1, in step S15 illustrated in FIG. 6, it is determined that the degree of deposition of the cells CE has not reached the reference amount (NO in step S15).

On the other hand, as illustrated in FIG. 7, at time t2, the cells CE are deposited to the height h2 in the cell holding unit 22. The height h2 is more than or equal to the height from the bottom portion 22a of the cell holding unit 22 to the baseline BL. Accordingly, at time t2, in step S15 illustrated in FIG. 6, it is determined that the degree of deposition of the cells CE has reached the reference amount (YES in step S15).

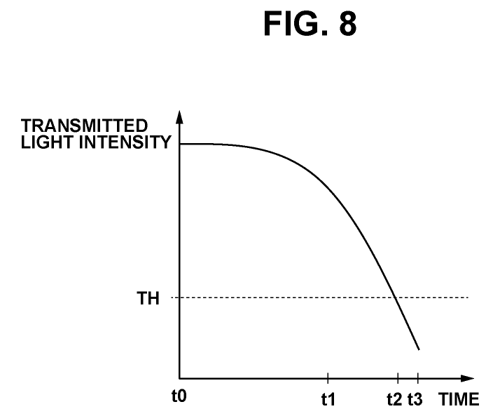

Next, a relationship between time t0 to time t2 described above and the transmitted light intensity detected by the detection mechanism 5 will be described with reference to FIG. 8. FIG. 8 is a graph illustrating an example of a change in the transmitted light intensity in the cell separation device 1 according to the first embodiment.

As illustrated in FIG. 8, at time t0, the cells CE are not deposited in the cell holding unit 22, and thus the transmitted light intensity has a maximum value in this graph. After that, during the period from time t0 to time t2, the transmitted light intensity gradually decreases from the transmitted light intensity at time t0 as the cells CE are gradually deposited. At time t2, the transmitted light intensity is less than or equal to a threshold TH. In this case, the threshold TH corresponds to the transmitted light intensity when the height of the cells CE deposited in the cell holding unit 22 has reached to the height from the bottom portion 22a of the cell holding unit 22 to the baseline BL. Accordingly, at time t2, the determination function 83 of the processing circuitry 8 determines that the transmitted light intensity obtained by the detection control function 82 of the processing circuitry 8 is less than or equal to the threshold. In other words, it is determined that the degree of deposition of the cells CE has reached the reference amount at time t2.

In the first embodiment, also after the delivery of the sample S is stopped at time t2 illustrated in FIG. 8, the cells CE remaining in the flow path 23 or the like flow into the cell holding unit 22. Accordingly, if the transmitted light intensity is measured at time t3, which is later than time t2, the transmitted light intensity at time t3 is less than the transmitted light intensity at time t2.

As described above, the cell separation device 1 according to the first embodiment detects the degree of deposition of the cells CE in the cell holding unit 22, and stops delivery of the sample by the liquid delivery mechanism 6 when it is determined that the degree of deposition has reached the reference amount. Thus, the amount of the sample S to be delivered by the liquid delivery mechanism 6 can be changed depending on a change in the amount of the cells CE in the sample S. In other words, even when the amount of the cells CE in the sample S varies depending on the sample S, the cells CE can be efficiently separated from the sample S. Specifically, if the sample S is blood collected from a patient and the cells CE in the sample S are blood cell components, variation in the efficiency of separating supernatant from blood due to the influence of the hematocrit level can be reduced.

In the cell separation device 1 according to the first embodiment, the reference amount used for determination of the degree of deposition is set to a range in which the degree of separation of cells in the cell holding unit 22 can be maintained if the degree of deposition is less than or equal to the reference amount. With this configuration, the cells CE can be prevented from mixing into the supernatant and high-purity supernatant can be stably collected.

In the cell separation device 1 according to the first embodiment, the stop function 85 may adjust the amount of the sample S to be delivered by the liquid delivery mechanism 6 based on the degree of deposition of cells in the cell holding unit 22. For example, the stop function 85 controls the liquid delivery mechanism 6 to decrease the amount of the sample S to be delivered as the degree of deposition approaches the reference amount. The amount of the sample S to be delivered may be determined based on, for example, the relationship between the degree of deposition and the amount of sample liquid to be delivered that is preliminarily stored in the storage circuitry, or may be calculated by the stop function 85 based on the degree of deposition. Thus, since the flow rate of the sample S decreases as the cells CE are gradually deposited, the cells CE deposited in the cell holding unit 22 can be further prevented from being output from the sample output unit 4. In place of the stop function 85, the liquid delivery control function 81 may adjust the amount of the sample S to be delivered by the liquid delivery mechanism 6 based on the degree of deposition of the cells CE in the cell holding unit 22.

In the cell separation device 1 according to the first embodiment, if the liquid delivery control function 81 controls the liquid delivery mechanism 6 to intermittently supply the sample S, the stop function 85 may adjust the amount of the sample S to be delivered once by the liquid delivery mechanism 6 based on the degree of deposition of the cells CE in the cell holding unit 22. For example, the stop function 85 may control the liquid delivery mechanism 6 to decrease the amount of the sample S to be delivered at a time as the degree of deposition approaches the reference amount. Thus, since the flow rate of the sample S decreases as the cells CE are gradually deposited, the cells CE deposited in the cell holding unit 22 can be further prevented from being output from the sample output unit 4.

In the cell separation device 1 according to the first embodiment, if the stop function 85 adjusts the amount of sample liquid to be delivered by the liquid delivery mechanism 6 based on the degree of deposition of the cells CE in the cell holding unit 22, the determination function 83 may be omitted. Differences between the first embodiment and Modified Example 1 of the first embodiment in which the determination function 83 is omitted will be mainly described below.

### Modified Example 1 of First Embodiment

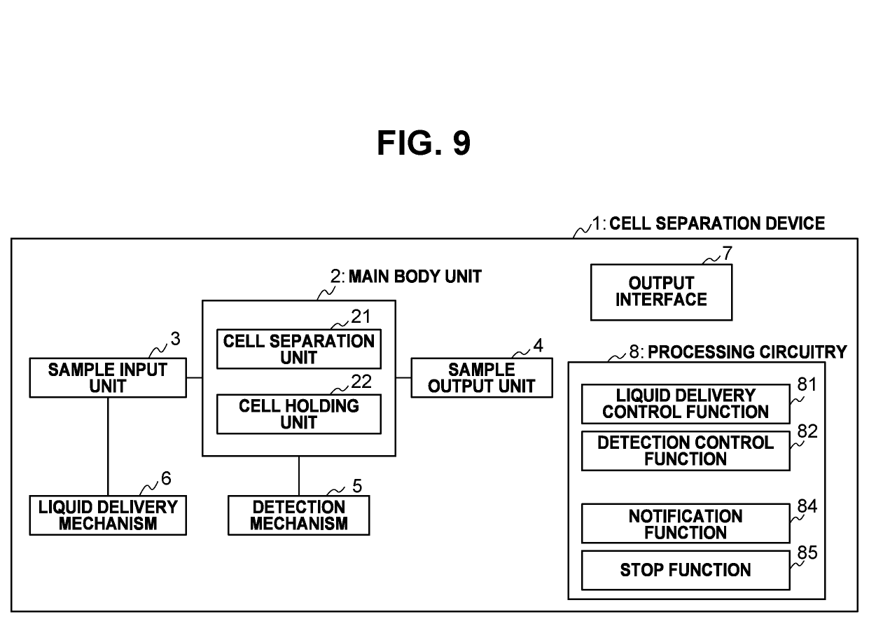

FIG. 9 is a block diagram illustrating a configuration example of the cell separation device 1 according to Modified Example 1 of the first embodiment. As illustrated in FIG. 9, in Modified Example 1, the processing circuitry 8 is not provided with the determination function 83.

In Modified Example 1, the stop function 85 of the processing circuitry 8 stops delivery of sample liquid by the liquid delivery mechanism 6 based on the degree of deposition of the cells CE in the cell holding unit 22. For example, the stop function 85 controls the liquid delivery mechanism 6 to decrease the amount of the sample S to be delivered as the degree of the deposition of the cells CE in the cell holding unit 22 approaches the reference amount. Further, the stop function 85 controls the liquid delivery mechanism 6 to stop delivery of the sample S when the degree of deposition of the cells CE has reached the reference amount.

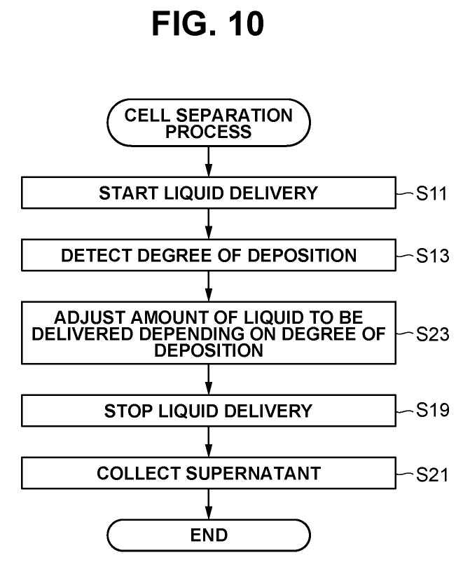

Next, an example of the cell separation process in the cell separation device 1 according to Modified Example 1 will be described with reference to FIG. 10. FIG. 10 is a flowchart illustrating an example of the cell separation process in the cell separation device 1 according to Modified Example 1 of the first embodiment. Steps S11 and S13 are similar to those in the first embodiment described above, and thus description thereof is omitted.

After step S13, in step S23, the cell separation device 1 adjusts the amount of sample liquid to be delivered depending on the degree of deposition. More specifically, the stop function 85 of the processing circuitry 8 controls driving of the pump 61 of the liquid delivery mechanism 6 illustrated in FIG. 3 depending on a detection result from the detection mechanism 5. For example, as illustrated in FIG. 8, the stop function 85 decreases the driving amount of the pump 61 as the transmitted light intensity approaches the threshold TH.

Next, as illustrated in FIG. 10, in step S19, the cell separation device 1 stops delivery of the sample S. More specifically, if the transmitted light intensity is less than or equal to the threshold TH, the stop function 85 of the processing circuitry 8 stops driving of the pump 61 of the liquid delivery mechanism 6 illustrated in FIG. 3. Step S21 and subsequent steps are similar to those in the first embodiment described above, and thus description thereof is omitted.

According to the cell separation device 1 of Modified Example 1, the detection result from the detection mechanism 5 is fed back to the liquid delivery mechanism 6, thereby making it possible to achieve the cell separation device 1 similar to that of the first embodiment even when the determination function 83 is omitted.

### Modified Example 2 of First Embodiment

In the first embodiment described above, the cell separation unit 21 is a T-shaped branch path and the cell holding unit 22 is a groove that can accommodate the cells CE. In Modified Example 2 of the first embodiment to be described below, the cell separation unit 21 and the cell holding unit 22 are each composed of a filter. Differences between the first embodiment and Modified Example 2 will be mainly described below.

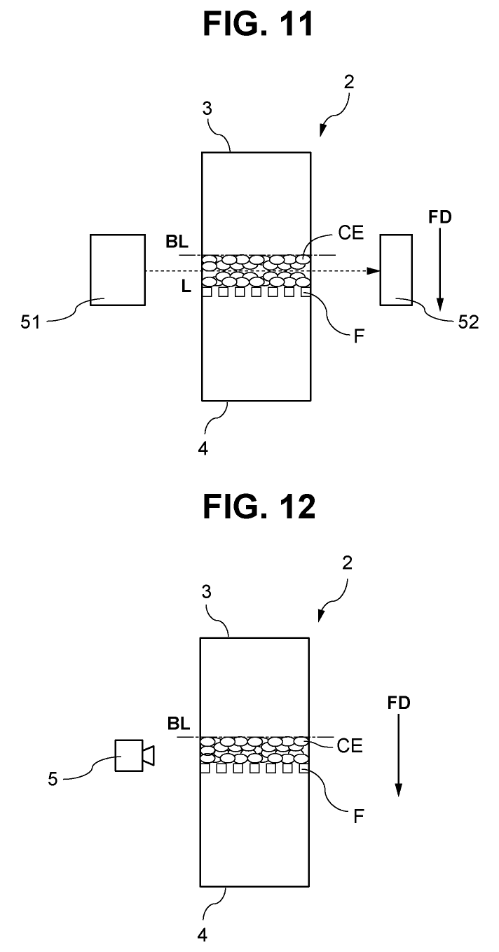

FIG. 11 is a schematic side view illustrating a configuration example of the cell separation device 1 according to Modified Example 2 of the first embodiment. As illustrated in FIG. 11, in Modified Example 2, the main body unit 2 has an I-shaped side surface structure. The main body unit 2 is, for example, a cylinder having openings at an upper end and a lower end, respectively. The upper-end opening of the main body unit 2 corresponds to the sample input unit 3, and the lower-end opening of the main body unit 2 corresponds to the sample output unit 4. A filter F is placed between the sample input unit 3 and the sample output unit 4. This filter F corresponds to each of the cell separation unit 21 and the cell holding unit 22 according to Modified Example 2.

The sample S in the sample container SC is input into the main body unit 2 from the sample input unit 3 by the pump included in the liquid delivery mechanism 6 (not illustrated). After that, the sample S flows along the flow direction FD in the main body unit 2. The filter F is provided on the flow path in the main body unit 2. When the sample S reaches the filter F, the cells CE in the sample S are captured by the filter F. The supernatant of the sample S passes through the filter F and is then output from the sample output unit 4.

In Modified Example 2, the detection mechanism 5 includes the light-emitting unit 51 and the light-receiving unit 52. The degree of deposition of the cells CE in the cell holding unit 22 is detected as, for example, the height of the cells CE deposited on the filter F. The reference amount for the degree of deposition is defined by, for example, the height from the upper surface of the filter F to the baseline BL. This reference amount is determined based on, for example, the strength of the filter F, the strength of fixing the filter F into the main body unit 2, the amount of the sample S to be delivered by the liquid delivery mechanism 6, and the like. The reference amount may be set to a range in which the cells CE deposited on the filter F are not destroyed by their pressure.

According to the cell separation device 1 of Modified Example 2, the cell separation unit 21 and the cell holding unit 22 can be composed of the filter F.

The detection mechanism 5 may be an image sensor. FIG. 12 is a schematic side view illustrating another configuration example of the cell separation device 1 according to Modified Example 2 of the first embodiment. In the example illustrated in FIG. 12, the detection mechanism 5 is an image sensor provided on a side of the main body unit 2. This image sensor obtains an image of the cells CE deposited on the filter F. After that, the obtained image is analyzed by the processing circuitry 8 or the like, so that the height of the cells CE deposited on the filter F can be calculated.

### Second Embodiment

In the first embodiment described above, the cells CE are separated by the cell separation unit 21 using the force of gravity. In a second embodiment to be described below, a force field for separating the cells CE is generated in the cell separation unit 21. Differences between the first embodiment and the second embodiment will be mainly described below.

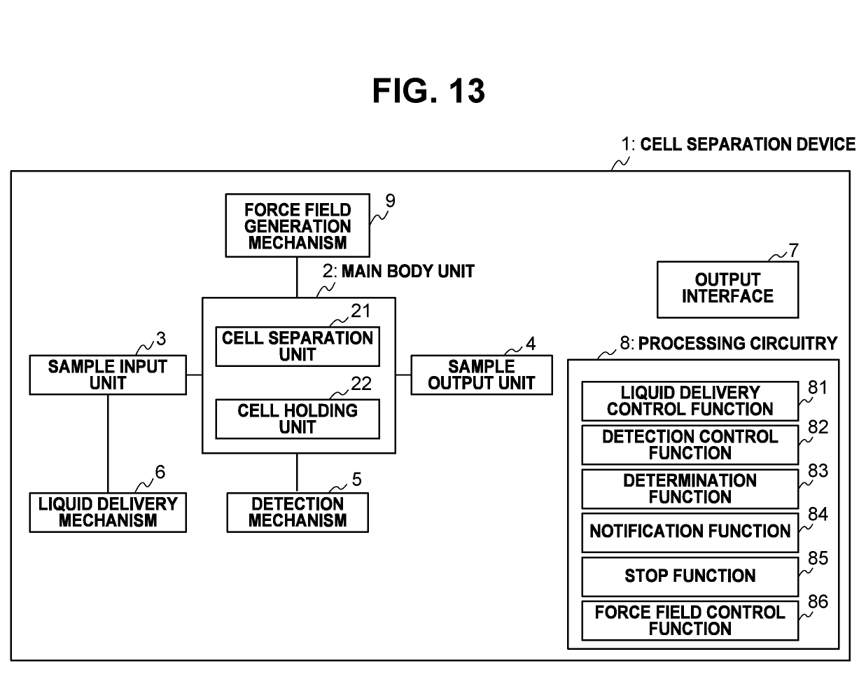

FIG. 13 is a block diagram illustrating a configuration example of the cell separation device 1 according to the second embodiment. As illustrated in FIG. 13, the cell separation device 1 according to the second embodiment includes a force field generation mechanism 9 in addition to the units of the cell separation device 1 according to the first embodiment. The processing circuitry 8 according to the second embodiment includes a force field control function 86 in addition to the processing functions of the processing circuitry 8 according to the first embodiment.

The force field generation mechanism 9 generates a force field for separating the cells CE from the sample S in the cell separation unit 21. The generated force field is applied to the cells CE located within the cell separation unit 21, and a force in the direction of the cell holding unit 22 acts on the cells CE. The force field generation mechanism 9 generates, as the force field, for example, at least one of an electric field, a magnetic field, and an acoustic field. The force field generation mechanism 9 includes an electrode or the like for generating the force field. The electrode is, for example, a comb electrode, a coil, or an acoustic transducer. The force field generation mechanism 9 may be integrated with the main body unit 2, or may be separated from the main body unit 2. The force field generation mechanism 9 corresponds to a force field generation unit according to the second embodiment.

The force field control function 86 of the processing circuitry 8 controls the operation of the force field generation mechanism 9 to cause the force field generation mechanism 9 to generate the force field in the cell separation unit 21. The force field control function 86 controls the operation of the force field generation mechanism 9 based on, for example, an instruction from the user or a program stored in the storage circuitry.

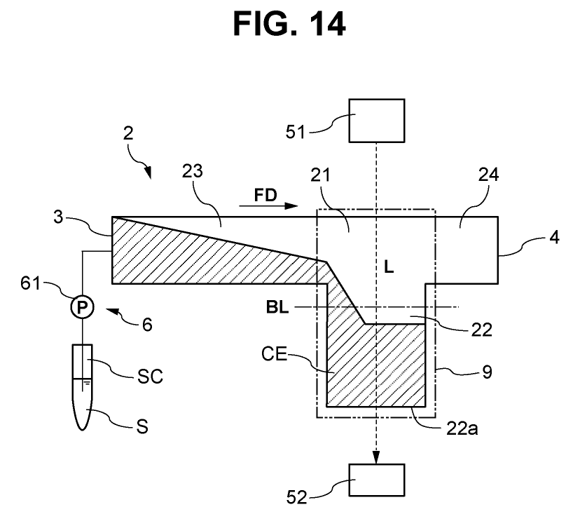

Next, a specific configuration example of the cell separation device 1 according to the second embodiment will be described with reference to FIG. 14. FIG. 14 is a schematic side view illustrating a configuration example of the cell separation device 1 according to the second embodiment.

As illustrated in FIG. 14, the force field generation mechanism 9 is integrated with, for example, the cell separation unit 21 and the cell holding unit 22, and generates a force field to be applied to the cells CE in the cell separation unit 21 and the cell holding unit 22. In the example illustrated in FIG. 14, the generated force field causes a downward force to act on the cells CE located within the cell separation unit 21 and the cell holding unit 22. The force field generation mechanism 9 may be provided on at least the cell separation unit 21. Alternatively, the force field generation mechanism 9 may also be provided on the flow path 23 and may also apply the force field to the cells CE flowing through the flow path 23.

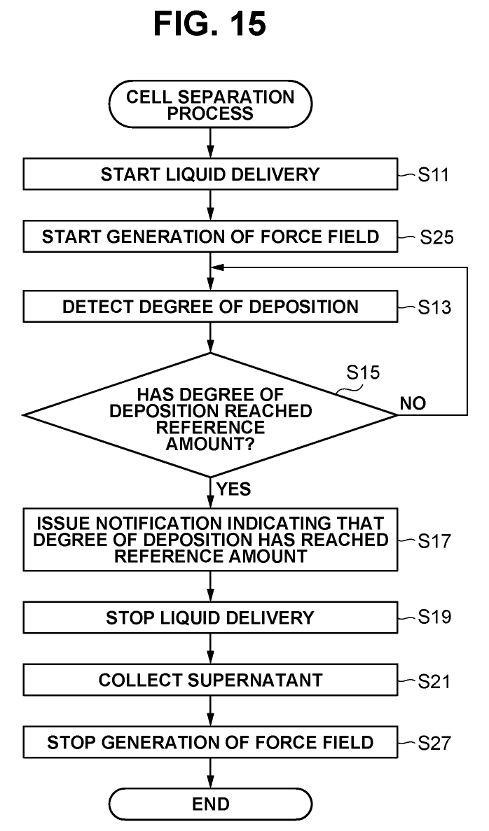

Next, an example of the cell separation process in the cell separation device 1 according to the second embodiment having a configuration as described above will be described with reference to FIG. 15. FIG. 15 is a flowchart illustrating an example of the cell separation process in the cell separation device 1 according to the second embodiment. Step S11 is similar to that in the first embodiment, and thus description thereof is omitted.

After step S11, in step S25, the cell separation device 1 starts generation of a force field. More specifically, the force field control function 86 of the processing circuitry 8 starts the operation of the force field generation mechanism 9 illustrated in FIG. 14 to generate the force field to be applied to the cells CE in the cell separation unit 21. As illustrated in FIG. 15, after step S25, steps S13 to S21 are carried out. Steps S13 to S21 are similar to those in the first embodiment, and thus description thereof is omitted.

After step S21, in step S27, the cell separation device 1 stops generation of the force field. More specifically, the force field control function 86 of the processing circuitry 8 stops the operation of the force field generation mechanism 9. After step S27, the operation of the cell separation device 1 according to the second embodiment ends.

According to the second embodiment, the application of the force field to the cells CE in the cell separation unit 21 promotes the separation of the cells CE by the cell separation unit 21. Consequently, the cells CE can be more efficiently separated from the sample S.

In the second embodiment, the force field is also applied to the cells CE in the cell holding unit 22. This configuration prevents the cells CE deposited in the cell holding unit 22 from flowing out to the sample output unit 4 when the amount of sample liquid to be delivered by the liquid delivery mechanism 6 is large, or when the main body unit 2 is inclined. Further, a larger amount of cells CE can be deposited in the cell holding unit 22, and the size of the cell separation device 1 can be reduced.

In the second embodiment, after the supernatant is collected in step S21 illustrated in FIG. 15, the generation of the force field is stopped in step S27. This prevents the cells CE from mixing into the supernatant when the supernatant is collected.

### Third Embodiment

Next, a third embodiment in which a function for discarding the cells CE deposited in the cell holding unit 22 and a function for cleaning the main body unit 2 are added to the second embodiment described above will be described. The function for discarding the cells CE and the function for cleaning the main body unit 2 may also be added to the cell separation device 1 according to the first embodiment, the cell separation device 1 according to Modified Example 1 of the first embodiment, and the cell separation device 1 according to Modified Example 2 of the first embodiment.

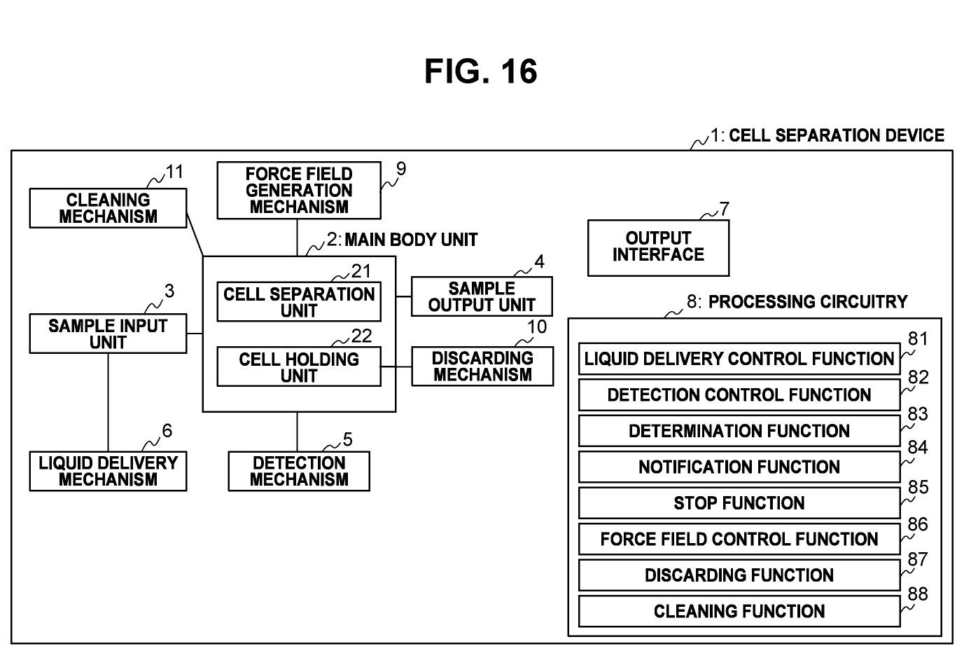

FIG. 16 is a block diagram illustrating a configuration example of the cell separation device 1 according to the third embodiment. As illustrated in FIG. 16, the cell separation device 1 according to the third embodiment includes a discarding mechanism 10 and a cleaning mechanism 11 in addition to the units of the cell separation device 1 according to the second embodiment. The processing circuitry 8 according to the third embodiment includes a discarding function 87 and a cleaning function 88 in addition to the processing functions of the processing circuitry 8 according to the second embodiment.

The discarding mechanism 10 is fluidically connected to the cell holding unit 22 and discards the cells CE held in the cell holding unit 22. The discarding mechanism 10 includes, for example, a valve for opening or closing the bottom portion 22a of the cell holding unit 22, and a waste liquid collection unit. In the waste liquid collection unit, a waste liquid bottle or the like for accommodating the discarded cells CE is placed. The discarding mechanism 10 corresponds to a discarding unit according to the third embodiment.

The cleaning mechanism 11 is fluidically connected to the main body unit 2 and cleans the main body unit 2. The cleaning mechanism 11 includes, for example, a cleaning liquid storage unit that stores the cleaning liquid bottle that contains the cleaning liquid, and a pump for delivering the cleaning liquid to the main body unit 2. Examples of the cleaning liquid include pure water, alkaline detergent, and acid detergent. The cleaning mechanism 11 corresponds to a cleaning unit according to the third embodiment.

The discarding function 87 of the processing circuitry 8 controls the discarding mechanism 10 to cause the discarding mechanism 10 to discard the cells CE. The cleaning function 88 of the processing circuitry 8 controls the cleaning mechanism 11 to cause the cleaning mechanism 11 to clean the main body unit 2. The discarding function 87 and the cleaning function 88 control the operations of the discarding mechanism 10 and the cleaning mechanism 11 based on, for example, an instruction from the user or a program stored in the storage circuitry.

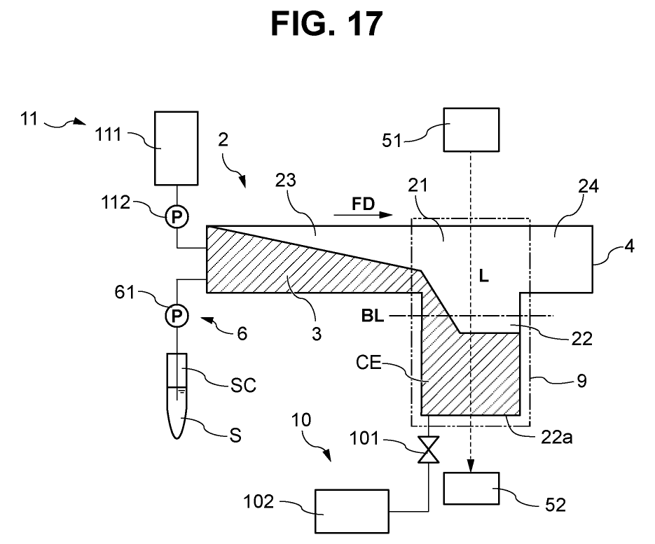

Next, a specific configuration example of the main body unit 2 according to the third embodiment will be described with reference to FIG. 17. FIG. 17 is a schematic side view illustrating a configuration example of the cell separation device 1 according to the third embodiment.

As illustrated in FIG. 17, the discarding mechanism 10 includes, for example, a valve 101 and a waste liquid collection unit 102. In the example illustrated in FIG. 15, the valve 101 is fluidically connected to the bottom portion 22a of the cell holding unit 22 so as to open or close the bottom portion 22a of the cell holding unit 22. When the valve 101 is opened, the cells CE deposited in the cell holding unit 22 are output to the waste liquid collection unit 102. The waste liquid collection unit 102 collects the cells CE output from the cell holding unit 22 into the waste liquid bottle.

The cleaning mechanism 11 includes a cleaning liquid storage unit 111 and a pump 112. In the example illustrated in FIG. 17, the cleaning mechanism 11 is connected to the sample input unit 3 and delivers the cleaning liquid into the main body unit 2 through the sample input unit 3.

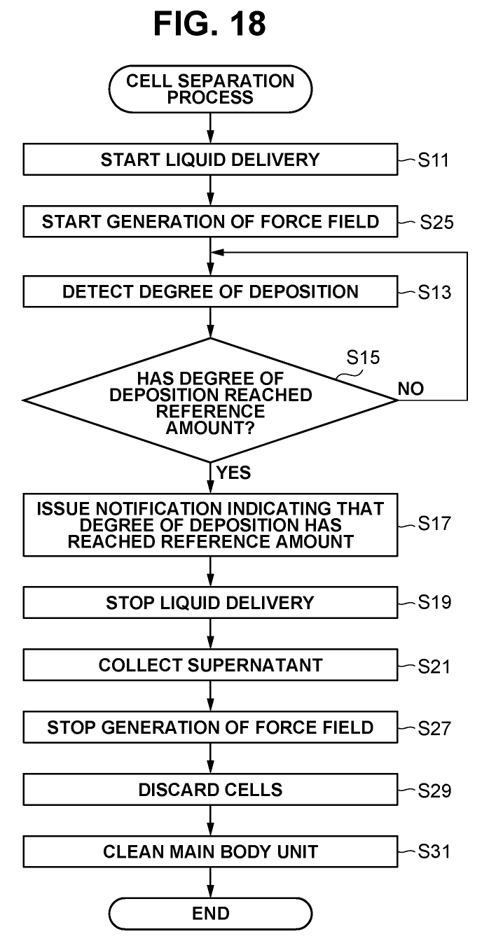

Next, an example of the cell separation process in the cell separation device 1 according to the third embodiment will be described with reference to FIG. 18. FIG. 18 is a flowchart illustrating an example of the cell separation process in the cell separation device 1 according to the third embodiment. Steps S11 to S27 illustrated in FIG. 18 are similar to those in the second embodiment described above, and thus description thereof is omitted.

After step S27, in step S29, the cell separation device 1 discards the cells CE. More specifically, the discarding function 87 of the processing circuitry 8 opens the valve 101 illustrated in FIG. 17, thereby causing the waste liquid collection unit 102 to output the cells CE deposited in the cell holding unit 22. The discarding function 87 may control the detection mechanism 5 to detect the degree of deposition of the cells CE, and may determine whether discarding of the cells CE is completed based on the detected degree of deposition.

Next, as illustrated in FIG. 18, in step S31, the cell separation device 1 cleans the main body unit 2. More specifically, the cleaning function 88 of the processing circuitry 8 drives the pump 112 illustrated in FIG. 17, thereby delivering the cleaning liquid into the main body unit 2 from the cleaning liquid bottle stored in the cleaning liquid storage unit 111. After step S31, the operation of the cell separation device 1 according to the third embodiment ends.

According to the cell separation device 1 according to the third embodiment, the provision of the discarding mechanism 10 for discarding the cells CE held in the cell holding unit 22 makes it possible to efficiently discard the cells CE. With this configuration, for example, the cell separation process can be efficiently repeated also for blood that has a higher hematocrit level and includes the cells CE to be deposited more quickly.

The cell separation device 1 according to the third embodiment includes the cleaning mechanism 11 for cleaning the main body unit 2, which makes it possible to repeatedly use the cell separation device 1. In the case of using different samples S, the influence of contamination can be reduced. The function for cleaning the main body unit 2 may also be added to the cell separation device 1 according to the first embodiment, the cell separation device 1 according to Modified Example 1 of the first embodiment, and the cell separation device 1 according to Modified Example 2 of the first embodiment.

If the influence of contamination is small, the function for cleaning the main body unit 2 may be omitted. Examples of this case include a case where the same sample S is delivered again to separate the cells CE in the sample S. In this case, the cell separation process can be efficiently repeated.

### Other Modified Examples

In the embodiments described above, the cell separation device 1 automatically delivers the sample S into the main body unit 2 by the liquid delivery mechanism 6 and the liquid delivery control function 81, and automatically stops delivery of the sample S by the stop function 85. The configuration of the cell separation device 1 is not limited to this example. The cell separation device 1 may be configured to manually deliver the sample S into the main body unit 2. In this case, in the cell separation device 1, the liquid delivery mechanism 6, the liquid delivery control function 81, and the stop function 85 may be omitted, and a syringe or the like may be connected to the sample input unit 3 in place of the liquid delivery mechanism 6. For example, the user can operate the syringe or the like to manually deliver the sample S into the main body unit 2. After that, when it is determined that the degree of deposition has reached the reference amount, the notification function 84 notifies the user of the determination result. The user decelerates or stops the operation of the syringe or the like depending on the determination result. With this configuration, the cell separation device 1 can be produced at low cost.

The term "processor" used herein refers to circuitry such as a central processing unit (CPU), a graphical processing unit (GPU), an application specific integrated circuit (ASIC), or a programmable logic device (a simple programmable logic device (SPLD), a complex programmable logic device (CPLD), and a field programmable gate array (FPGA)). The processor reads out programs stored in storage circuitry and executes the programs, thereby implementing the functions. Instead of storing programs in the storage circuitry, programs may be directly incorporated in the processor circuitry. In this case, the processor reads out the programs incorporated in the circuitry and executes the programs, thereby implementing the functions. Instead of being composed of a single circuitry, the processor may be composed of a plurality of independent circuitries as one processor to implement the functions. Furthermore, a plurality of constituent elements illustrated in FIG. 1 may be integrated into one processor to implement the functions.

According to at least one of the above-described embodiments, it is possible to efficiently separate cells from a sample even when the amount of cells in the sample varies depending on the sample.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cell separation device that separates cells from a sample including the cells, the cell separation device comprising:
a cell holding unit configured to hold the cells separated from the sample;
a detection unit configured to detect a degree of deposition of the cells in the cell holding unit; and
processing circuitry configured to determine whether the degree of deposition has reached a reference amount.

2. A cell separation device that separates cells from a sample including the cells, the cell separation device comprising:
a cell holding unit configured to hold the cells separated from the sample;
a detection unit configured to detect a degree of deposition of the cells in the cell holding unit;
a liquid delivery unit configured to deliver the sample to a main body unit including the cell holding unit from a sample container; and
processing circuitry configured to stop delivery of the sample by the liquid delivery unit based on the degree of deposition.

3. The cell separation device according to claim 1, further comprising:
a liquid delivery unit configured to deliver the sample to a main body unit including the cell holding unit from a sample container,
wherein the processing circuitry is further configured to stop delivery of the sample by the liquid delivery unit in a case where it is determined that the degree of deposition has reached the reference amount.

4. The cell separation device according to claim 2, wherein the processing circuitry is configured to adjust an amount of the sample to be delivered by the liquid delivery unit depending on the degree of deposition.

5. The cell separation device according to claim 4, wherein the processing circuitry is configured to control the liquid delivery unit to decrease the amount of the sample to be delivered as the degree of deposition approaches the reference amount.

6. The cell separation device according to claim 1, wherein the processing circuitry is further configured to notify a user of a result of the determination.

7. The cell separation device according to claim 1, further comprising:
a main body unit including the cell holding unit and a cell separation unit fluidically connected to the cell holding unit, the cell separation unit being configured to separate cells in the sample;
a sample input unit configured to input the sample to the main body unit; and
a sample output unit configured to output the sample from which the cells have been removed from the main body unit.

8. The cell separation device according to claim 7, further comprising a force field generation unit configured to generate a force field for separating the cells from the sample in the cell separation unit.

9. The cell separation device according to claim 8, wherein the force field generation unit generates at least one of an electric field, a magnetic field, and an acoustic field as the force field.

10. The cell separation device according to claim 7, further comprising a cleaning unit configured to clean the main body unit.

11. The cell separation device according to claim 7, wherein the cell holding unit is a groove configured to accommodate the cells separated by the cell separation unit.

12. The cell separation device according to claim 7, wherein the cell holding unit is a filter configured to capture the cells separated by the cell separation unit.

13. The cell separation device according to claim 1, further comprising a discarding unit configured to discard the cells held in the cell holding unit.

14. The cell separation device according to claim 1, wherein the detection unit obtains, as the degree of deposition, optical information about the cells deposited in the cell holding unit.

15. The cell separation device according to claim 1, wherein the sample is blood and the cells are blood cell components in the blood.

16. A cell separation method for separating cells from a sample including the cells, the cell separation method comprising:
holding the cells separated from the sample in a cell holding unit;
detecting a degree of deposition of the cells in the cell holding unit; and
determining whether the degree of deposition has reached a reference amount.

17. A cell separation method for separating cells from a sample including the cells, the cell separation method comprising:
delivering the sample from a sample container to a main body unit;
holding the cells separated from the sample in a cell holding unit provided in the main body unit;
detecting a degree of deposition of the cells in the cell holding unit; and
stopping the delivery of the sample based on the degree of deposition.
